(19) United States
(12) Patent Application Publication
(10) Pub. No.: US 2023/0358710 A1
(43) Pub. Date: Nov. 9, 2023

(54) ULTRASONIC TRANSDUCER ASSEMBLY AND RELATED METHODS

(71) Applicant: E2SENSE INC., Quebec (CA)

(72) Inventors: Eric ROCHEFORT, Quebec (CA); Erick PELLETIER, Quebec (CA)

(21) Appl. No.: 18/029,208

(22) PCT Filed: Sep. 30, 2021
(86) PCT No.: PCT/CA2021/051367

§ 371 Date: Mar. 29, 2023

Related U.S. Application Data
(60) Provisional application No. 63/085,597, filed on Sep. 30, 2020.

(51) Int. Cl. G01N 29/24; H05K 1/18

(52) U.S. Cl. CPC G01N 29/245; H05K 1/189; G01N 2291/106

(57) ABSTRACT

There is provided an ultrasonic transducer assembly for inspecting a sample. The assembly includes a support, a flexible printed circuit board having proximal and distal ends, the proximal end being affixed to the support and the distal end extending away from the support, one transducer or an array of transducers mounted on the support and positioned near or at the proximal end, each transducer being made from a flexible porous piezoelectric material and being operatively connected to the flexible printed circuit board, and a power unit mounted on the flexible printed circuit board and positioned near or at the distal end, the power unit being operatively connected to the flexible printed circuit board. The flexible printed circuit board comprises conductive channel(s). There are also provided methods for manufacturing the assembly and methods for inspecting the sample.

### TECHNICAL FIELD

The technical field generally relates to the field of ultrasonic technologies, and more particularly relates to an ultrasonic transducer assembly and related methods.

### BACKGROUND

Commercially available systems and/or methods for inspecting samples present several drawbacks and limitations, notably in terms of defect identification capability, precision and/or overall process speed. Various challenges remain in the field of inspecting samples with ultrasonic transducers.

There is still a need for techniques, apparatuses, devices, and methods that alleviate or mitigate the problems of prior art.

### SUMMARY

In accordance with one aspect, there is provided an ultrasonic transducer assembly for inspecting a sample, the ultrasonic transducer assembly including:
a support;
a flexible printed circuit board having a proximal end and a distal end, the proximal end being affixed to the support and the distal end extending away from the support;
an array of transducers mounted on the support and positioned near or at the proximal end of the flexible printed circuit board, each transducer being made from a flexible porous piezoelectric material and being operatively connected to the flexible printed circuit board; and
a power unit mounted on the flexible printed circuit board and positioned near or at the distal end of the flexible printed circuit board, the power unit being operatively connected to the flexible printed circuit board;
   wherein the flexible printed circuit board includes conductive channels operatively connecting the array of transducers to the power unit.

In some embodiments, the support is a sheet made from a metal or a metal alloy.

In some embodiments, the support is flexible.

In some embodiments, the support is rigid.

In some embodiments, each transducer of the array of transducers includes a respective transducer contact and the flexible printed circuit board includes a plurality of conductive pads positioned near or at the proximal end of the flexible printed circuit board, the respective transducer contact being in electrical communication with a corresponding conductive pad.

In some embodiments, the respective transducer contact is affixed to the corresponding conductive pad with an electrically conductive glue or an electrically conductive epoxy.

In some embodiments, each conductive pad has a width of about 0.3 mm or less.

In some embodiments, the proximal end of the flexible board is affixed to the support with an electrically conductive glue or an electrically conductive epoxy.

In some embodiments, the power unit includes wires, connectors, or plugs.

In some embodiments, the flexible printed circuit board includes at least one ground.

In some embodiments, the ultrasonic transducer assembly further includes a second support, the distal end of the flexible printed circuit board being affixed to the second support.

In some embodiments, the second support is rigid.

In some embodiments, the second support is flexible.

In some embodiments, the flexible printed circuit board includes a plurality of conducting layers, each conducting layer including at least one of the conductive channels.

In some embodiments, the flexible printed circuit board includes at least one insulating layer, each insulating layer being provided between two successive layers of the plurality of the conducting layers.

In some embodiments, the number of conductive channels is included between 2 and 256, 2 to 128, 2 to 64, 2 to 32, 2 to 16, 2 to 8, or 2 to 4.

In some embodiments, the ultrasonic transducer assembly includes one transducer and one conductive channel.

In some embodiments, the ultrasonic transducer assembly has a thickness of about 1 mm or less.

In some embodiments, the array of transducers is configured to generate ultrasound having a center frequency included in a frequency range extending from about 0.5 MHz to about 50 MHz.

In some embodiments, the array of transducers has a constant pitch.

In some embodiments, the array of transducers has a variable pitch.

In some embodiments, the ultrasonic transducer assembly further includes a cladding or shielding covering at least a portion of the flexible printed circuit board, the cladding having mechanical properties and electrical properties.

In some embodiments, the mechanical properties include mechanical resistance.

In some embodiments, the electrical properties include electrical insulation.

In some embodiments, the ultrasonic transducer assembly further includes a seal extending over at least a portion the support, at least a portion of the array of transducers and at least a portion of the flexible printed circuit board, wherein the array of transducers and the flexible printed circuit board are sandwiched between the support and the seal.

In some embodiments, the seal is made from an electrically and thermally insulating material.

In some embodiments, the ultrasonic transducer assembly further includes a flexible cover, the flexible cover extending over the seal and mechanically contacting the support through the seal.

In accordance with another aspect, there is provided a method for manufacturing an ultrasonic transducer assembly, the method including:
providing a support and a flexible printed circuit board, the flexible printed circuit board having a proximal end and a distal end;
affixing the proximal end of the flexible circuit printed board to the support;
forming an array of transducers over the support, the array of transducers being formed near or at the proximal end of the flexible printed circuit board, each transducer being made from a flexible porous piezoelectric material;
providing a power unit on the flexible printed circuit board, near or at the distal end of the flexible printed circuit board; and
operatively connecting the array of transducers to the power unit with conductive channels provided on the flexible printed circuit board.

In some embodiments, the method further includes operatively connecting the array of transducers to the flexible printed circuit board.

In some embodiments, each transducer of the array of transducers includes a respective transducer contact and the flexible printed circuit board includes a plurality of conductive pads positioned near or at the proximal end of the flexible printed circuit board, said operatively connecting the array of transducers to the flexible printed circuit board including affixing the respective transducer contact with a corresponding conductive pad.

In some embodiments, the respective transducer contact is affixed to the corresponding conductive pad with an electrically conductive glue or an electrically conductive epoxy.

In some embodiments, the method further includes providing a second support and affixing the distal end of the flexible printed circuit board to the second support.

In some embodiments, the method further includes operatively connecting the power unit to the flexible printed circuit board.

In some embodiments, the method further includes forming the conductive channels on the flexible printed circuit board.

In some embodiments, said forming the array of transducers is achieved with a deposition technique.

In some embodiments, the method further includes covering at least a portion of the flexible printed circuit board with a cladding, the cladding having mechanical properties and electrical properties.

In some embodiments, the method further includes providing a seal extending over at least a portion the support, at least a portion of the array of transducers and at least a portion of the flexible printed circuit board, wherein the array of transducers and the flexible printed circuit board are sandwiched between the support and the seal.

In some embodiments, the method further includes providing a flexible cover extending over the seal and mechanically contacting the support.

In accordance with another aspect, there is provided a method for inspecting a sample, the method including:
contacting the sample with an ultrasonic transducer assembly as herein disclosed; and
obtaining a sample signal representative of at least one property of the sample.

In some embodiments, the method further includes driving the ultrasonic transducer assembly to generate an interrogating ultrasonic signal towards the sample, the interrogating ultrasonic signal interacting with the sample to produce the sample signal.

In some embodiments, the method further includes collecting the sample signal.

In some embodiments, the method further includes processing the sample signal to determine said at least one property of the sample.

In accordance with another aspect, there is provided an ultrasonic transducer assembly for inspecting a sample, the ultrasonic transducer assembly including:
a support;
a flexible printed circuit board having a proximal end and a distal end, the proximal end being affixed to the support and the distal end extending away from the support;
a transducer mounted on the support and positioned near or at the proximal end of the flexible printed circuit board, the transducer being made from a flexible porous piezoelectric material and being operatively connected to the flexible printed circuit board; and
a power unit mounted on the flexible printed circuit board and positioned near or at the distal end of the flexible printed circuit board, the power unit being operatively connected to the flexible printed circuit board;
   wherein the flexible printed circuit board includes conductive channels operatively connecting the transducer to the power unit.

In some embodiments, the support is a sheet made from a metal or a metal alloy.

In some embodiments, the support is flexible.

In some embodiments, the support is rigid.

In some embodiments, each transducer of the transducer includes a respective transducer contact and the flexible printed circuit board includes a plurality of conductive pads positioned near or at the proximal end of the flexible printed circuit board, the respective transducer contact being in electrical communication with a corresponding conductive pad.

In some embodiments, the respective transducer contact is affixed to the corresponding conductive pad with an electrically conductive glue or an electrically conductive epoxy.

In some embodiments, each conductive pad has a width of about 0.3 mm or less.

In some embodiments, the proximal end of the flexible board is affixed to the support with an electrically conductive glue or an electrically conductive epoxy.

In some embodiments, the power unit includes wires, connectors, or plugs.

In some embodiments, the flexible printed circuit board includes at least one ground.

In some embodiments, the ultrasonic transducer assembly further includes a second support, the distal end of the flexible printed circuit board being affixed to the second support

In some embodiments, the second support is rigid.

In some embodiments, the second support is flexible.

In some embodiments, the flexible printed circuit board includes a plurality of conducting layers, each conducting layer including at least one of the conductive channels.

In some embodiments, the flexible printed circuit board includes at least one insulating layer, each insulating layer being provided between two successive layers of the plurality of the conducting layers.

In some embodiments, the number of conductive channels is included between 2 and 256, 2 to 128, 2 to 64, 2 to 32, 2 to 16, 2 to 8, or 2 to 4.

In some embodiments, the ultrasonic transducer assembly has a thickness of about 4 mm or less, 3 mm or less, 2 mm or less, or 1 mm or less.

In some embodiments, the transducer is configured to generate ultrasound having a center frequency included in a frequency range extending from about 0.5 MHz to about 50 MHz.

In some embodiments, the ultrasonic transducer assembly further includes a cladding or shielding covering at least a portion of the flexible printed circuit board, the cladding having mechanical properties and electrical properties.

In some embodiments, the mechanical properties include mechanical resistance.

In some embodiments, the electrical properties include electrical insulation.

In some embodiments, the ultrasonic transducer assembly includes a seal extending over at least a portion the support, at least a portion of the transducer and at least a portion of the flexible printed circuit board, wherein the transducer and the flexible printed circuit board are sandwiched between the support and the seal.

In some embodiments, the seal is made from an electrically and thermally insulating material.

In some embodiments, the ultrasonic transducer assembly further includes a flexible cover, the flexible cover extending over the seal and mechanically contacting the support through the seal.

In accordance with another aspect, there is provided a method for inspecting a sample, the method including:
contacting the sample with an ultrasonic transducer assembly as herein disclosed; and
obtaining a sample signal representative of at least one property of the sample.

In some embodiments, the method further includes driving the ultrasonic transducer assembly to generate an interrogating ultrasonic signal towards the sample, the interrogating ultrasonic signal interacting with the sample to produce the sample signal.

In some embodiments, the method further includes collecting the sample signal.

In some embodiments, the method further includes processing the sample signal to determine said at least one property of the sample.

In accordance with another aspect, there is provided an ultrasonic transducer assembly for inspecting a sample, the ultrasonic transducer assembly including:
a conductive substrate;
an array of transducers disposed on the conductive substrate, each transducer being made from a flexible porous piezoelectric material;
a flexible printed circuit board, including:
   a flexible substrate having an outer perimeter, the flexible substrate contacting the conductive substrate;
   a plurality of electrical contacts distributed across a surface of the flexible printed circuit board and within the outer perimeter; and
   a plurality of channels contacting a portion of the outer perimeter and extending outwardly therefrom, each channel being operatively connected to a respective transducer of the array of transducers and a respective electrical contact of said plurality of electrical contacts; and
an electrical circuit configured to power the array of transducers, the electrical circuit including a plurality of electrical connections operatively connected to a respective electrical contact of said plurality of electrical contacts.

In some embodiments, the conductive substrate is a sheet made from a metal or a metal alloy.

In some embodiments, the electrical circuit includes at least one of wires, connectors, and plugs.

In some embodiments, the ultrasonic transducer assembly has a thickness of about 4 mm or less, 3 mm or less, 2 mm or less, or 1 mm or less.

In some embodiments, the array of transducers is configured to generate ultrasound having a center frequency included in a frequency range extending from about 0.5 MHz to about 50 MHz.

In some embodiments, the array of transducers has a constant pitch.

In some embodiments, the array of transducers has a variable pitch.

In some embodiments, the ultrasonic transducer assembly further includes a cladding covering at least a portion of the flexible printed circuit board, the cladding having mechanical properties and electrical properties.

In some embodiments, the mechanical properties include mechanical resistance.

In some embodiments, the electrical properties include electrical insulation.

In some embodiments, the ultrasonic transducer further includes a seal extending over at least a portion of the array of transducers and at least a portion of the flexible printed circuit board.

In some embodiments, the seal is made from an electrically insulating material.

In some embodiments, the ultrasonic transducer further includes a flexible cover, the flexible cover extending over the seal and mechanically contacting the support through the seal.

In accordance with another aspect, a method for manufacturing an ultrasonic transducer assembly, the method including:
providing an array of transducers disposed on a conductive substrate, each transducer being made from a flexible porous piezoelectric material;
providing a flexible printed circuit board, the flexible printed circuit including a flexible substrate having an outer perimeter, a plurality of electrical contacts distributed across a surface of the flexible printed circuit board and within the outer perimeter, and a plurality of channels;
connecting each channel with a respective transducer of the array of transducers;
providing an electrical circuit configured to power the array of transducers, the electrical circuit including a plurality of electrical connections; and
connecting each electrical connection to a respective electrical contact of said plurality of electrical contacts of said plurality of channels.

In accordance with another aspect, there is provided a method for inspecting a sample, the method including:
contacting the sample with an ultrasonic transducer assembly as described herein; and
obtaining a sample signal representative of at least one property of the sample.

In some embodiments, the method further includes driving the ultrasonic transducer assembly to generate an interrogating ultrasonic signal towards the sample, the interrogating ultrasonic signal interacting with the sample to produce the sample signal.

In some embodiments, the method further includes collecting the sample signal.

In some embodiments, the method further includes processing the sample signal to determine said at least one property of the sample.

Other features and advantages of the present description will become more apparent upon reading of the following non-restrictive description of specific embodiments thereof, given by way of example only with reference to the accompanying drawings.

### BRIEF DESCRIPTION OF THE DRAWINGS

FIG. 1 illustrates a schematical view of an ultrasonic transducer assembly, in accordance with one embodiment.

FIG. 2 illustrates a photograph of the ultrasonic transducer assembly of FIG. 1, provided with a flexible cover.

FIG. 3 illustrates a flowchart of a method for manufacturing an ultrasonic transducer assembly, in accordance with one embodiment.

FIG. 4 illustrates a schematical view of an ultrasonic transducer assembly, in accordance with another embodiment.

FIG. 5 illustrates a flowchart of a method for manufacturing an ultrasonic transducer assembly, in accordance with another embodiment.

### DETAILED DESCRIPTION

In the following description, similar features in the drawings have been given similar reference numerals, and, to not unduly encumber the figures, some elements may not be indicated on some figures if they were already identified in one or more preceding figures. It should also be understood herein that the elements of the drawings are not necessarily depicted to scale, since emphasis is placed upon clearly illustrating the elements and structures of the present embodiments. The terms “a”, “an” and “one” are defined herein to mean “at least one”, that is, these terms do not exclude a plural number of elements, unless stated otherwise. It should also be noted that terms such as “substantially”, “generally” and “about”, that modify a value, condition or characteristic of a feature of an exemplary embodiment, should be understood to mean that the value, condition or characteristic is defined within tolerances that are acceptable for the proper operation of this exemplary embodiment for its intended application.

In the present description, the terms “connected”, “coupled”, and variants and derivatives thereof, refer to any connection or coupling, either direct or indirect, between two or more elements. The connection or coupling between the elements may be acoustical, mechanical, physical, optical, operational, electrical, wireless, or a combination thereof.

It will be appreciated that positional descriptors indicating the position or orientation of one element with respect to another element are used herein for ease and clarity of description and should, unless otherwise indicated, be taken in the context of the figures and should not be considered limiting. It will be understood that spatially relative terms (e.g., “outer” and “inner”, “outside” and “inside”, “periphery” and “central”, and “top” and “bottom”) are intended to encompass different positions and orientations in use or operation of the present embodiments, in addition to the positions and orientations exemplified in the figures.

The expression “flexible”, variants and derivatives thereof, are used to describe a class of components, devices, circuits, assembly, and the like including deformable, conformable, and/or stretchable components, portions and/or layers. Nonlimitative of flexible materials are plastic, metal, metal alloys, metal foil, paper, flex glass, or any other materials having similar properties.

The term “alloy” refers to a material or a composition of materials including at least two different elements. For example, and without being limitative, an alloy could include two, three or four different elements. In the context of the current disclosure, the expression “metal alloy” refers to an alloy comprising at least one metal.

The description generally relates to an ultrasonic transducer assembly and more particularly concerns a flexible porous piezoelectric ultrasonic transducer assembly, as well as related methods. The technology and its advantages will become more apparent from the detailed description and examples that follow, which describe the various embodiments of the technology. More specifically, the following description will present an ultrasonic transducer assembly that may be used for inspecting samples, as well as related methods. In the context of this disclosure, the expression “sample” refers to any items that may be investigated or characterized, such as surfaces (flat and/or curved), parts, components, structures, materials, and any combinations thereof.

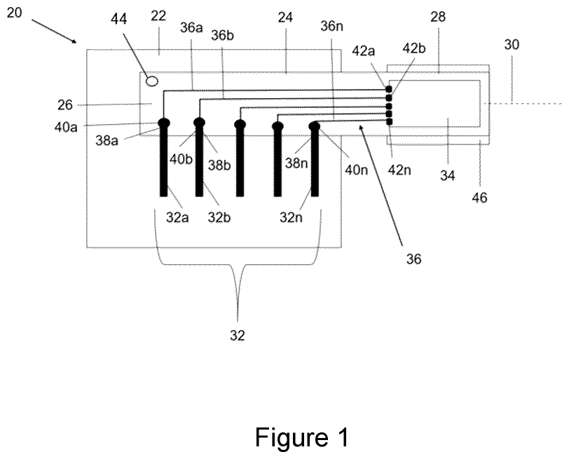

With reference to FIG. 1, a schematic illustration of an ultrasonic transducer assembly 20 for inspecting a sample is shown.

The ultrasonic transducer assembly 20 includes a support 22. In some embodiments, the support 22 may be flexible and may be deformable to conform to, for example and without being limitative, a curved outer surface of the sample (or a portion thereof). More specifically, in these embodiments, the support 22 has the required mechanical properties to be reversibly deformable, between, for example and without being limitative, a relatively flat configuration and at least one substantially curved or bent configuration, when an external force is exerted of the support 22. The external force could be applied by any mechanisms known in the art. A nonlimitative example of such mechanisms is a clamp. In other embodiments, the support 22 may be rigid or at least substantially rigid.

It will be noted that the ultrasonic transducer assembly 20 may be useful, for example, and without being limitative, in the context of structural health monitoring (SHM), non-destructive testing (NDT) or any other similar applications. It will be noted that, in use, the ultrasonic transducer assembly may directly contact the sample or indirectly contact the sample, for example through a contact layer (permanent or temporary contact layer), a block, a wedge, and/or any other components or means known in the art.

The ultrasonic transducer assembly 20 also includes a flexible printed circuit board 24 having a proximal end 26 and a distal end 28. In some embodiments, the proximal end 26 may be affixed to the support 22, and the distal end 28 extends outwardly and away from the support 22. In some embodiments, the flexible printed circuit board 24 has an elongated shape extending along a longitudinal axis 30, but it will be readily understood that the shape may vary according to the targeted applications. As illustrated in FIG. 1, the distal end 28 is not directly supported by the support 22. In some embodiments, the proximal end 26 of the flexible board 24 is affixed to the support 22 with an electrically conductive glue or an electrically conductive epoxy. The flexible printed circuit board 24 may include at least one ground 44.

Still referring to FIG. 1, the ultrasonic transducer assembly 20 also includes an array of transducers 32 provided on the support 22. The array of transducers 32 is positioned near or at the proximal end 26 of the flexible printed circuit board 24 (i.e., in a region opposite of the distal end 28 of the flexible printed circuit board 24). The array of transducers 32 generally includes a plurality of transducers, which may include a first transducer 32a, a second transducer, and up to n transducers, wherein n is a positive integer. Each transducer 32a, 32b, . . . , 32n is preferably made from a flexible porous piezoelectric material and is operatively connected to the flexible printed circuit board 24. Nonlimitative examples of flexible porous piezoelectric materials include lead zirconate titanate (PZT), bismuth titanate (BIT) and lithium niobate.

In some embodiments, the array of transducers 32 has a constant pitch, i.e., the spacing or the distance between any pairs of adjacent transducers is substantially the same. In other embodiments, the array of transducers 32 has a variable pitch, i.e., the spacing or the distance between any pairs of adjacent transducers is relatively different or at least not exactly the same.

The ultrasonic transducer assembly 20 also includes a power unit 34 provided on the flexible printed circuit board 24. The power unit 34 may be an electrical circuit. As illustrated, the power unit 34 is positioned near or at the distal end 28 of the flexible printed circuit board 24. The power unit 34 is operatively connected to the flexible printed circuit board 24. The power unit 34 may include one or more electrical circuit(s), which may be used for powering and/or driving the array of transducers 32. The design and configuration of power unit 34 may vary according to the targeted application, but generally includes electronics components, such as for example and without being limitative resistors, switches, amplifiers, filters, diodes, transistor, wires, plugs, connectors and/or any other components already known by one skilled in the art. The power unit 34 may be driven or controlled by a control unit (not illustrated) for operating the ultrasonic transducer assembly 20. The control unit may be operatively connected or part of a processor (not illustrated). As it will be readily understood, the processor may be implemented as a single unit or as a plurality of interconnected processing sub-units. Also, the processor may be embodied by a computer, smartphone, a microprocessor, a microcontroller, a central processing unit, or by any other type of processing resource or any combination of such processing resources configured to operate collectively as a processor. The processor may be implemented in hardware, software, firmware, or any combination thereof, and be connected to the components of the ultrasonic transducer assembly 20 via appropriate communication ports.

In the embodiment depicted in FIG. 1, the flexible printed circuit board 24 comprises conductive channels 36 operatively connecting the array of transducers 32 to the power unit 34. The conductive channels 36 generally includes a plurality of conductive channels, which may include a first conductive channel 36a, a second conductive channel 36b, and up to n conductive channels, wherein n is a positive integer. However, in other embodiments, only one ultrasonic transducer may be provided, for example in the context of an array including only one transducer. In that scenario, the array includes only one transducer, and associated with one corresponding conductive channel. Each conductive channel 36a, 36b, 36n may connect one transducer from the array of transducers 32 with the power unit 34. In some embodiments, each transducer 32a, 32b, 32n of the array of transducers 32 comprises a respective transducer contact 38a, 38b, . . . , 38, and the flexible printed circuit board 24 comprises a plurality of conductive pads 40a, 40b, 40n (globally referred to as the conductive pads 40). The conductive pads 40 are positioned near or at the proximal end 28 of the flexible printed circuit board 24 and each conductive pad has a width of about 0.3 mm or less. The respective transducer contact, e.g., the transducer contact 38a, may be in electrical communication with a corresponding conductive pad, e.g., the conductive pad 40a. In some embodiments the respective transducer contact, e.g., the transducer contact 38a may be affixed to the corresponding conductive pad, e.g., the conductive pad 40a with an electrically conductive glue. In the illustrated embodiment of FIG. 1, the electrical communication between each of the transducers 32a, 32b, 32n and the power unit 34 may be achieved through the conductive channels 36a, 36b, . . . , 36n, the transducer contacts 38a, 38b, 38n and the conductive pads 40a, 40b, 40n. It will be noted that the power unit 34 may include one or more ports 42a, 42b, 42n for receiving a corresponding one of the conductive channels 36a, 36b, 36n. Of note, the path between each transducer 32a, 32b, 32n and each port 42a, 42b, 42n may be referred as a “channel”. For example, the “channel A” would extend from the transducer 32a, the transducer contact 38a, the conductive pad 40a, the conductive channel 36a and the port 42a. Similarly, the “channel N” would extend from the transducer 32n, the transducer contact 38n, the conductive pad 40n, the conductive channel 36n and the port 42n, wherein n is a positive integer. Of note, the flexible printed circuit board 24 includes at least one ground operatively connecting the proximal end 26 with the distal end 28. It will be noted that the number of conductive channels 36 may comprised between 2 and 256, 2 to 128, 2 to 64, 2 to 32, 2 to 16, 2 to 8, or 2 to 4. In other embodiments, the ultrasonic transducer assembly 20 includes one transducer 32 (sometimes referred to as a “single element transducer”). In these embodiments, ultrasonic transducer assembly 20 includes one conductive channel 36.

It will be noted that the ultrasonic transducer assembly 20 (or at least portion(s) or component(s) thereof) may be, in some implementations, flexible. In some embodiments, the ultrasonic transducer assembly 20 may be flexed along one axis. In other embodiments, the ultrasonic transducer assembly 20 may be flexed along more than one axis, such as, for example and without being limitative, two, three, four or even more axes. In these embodiments, the ultrasonic transducer assembly 20 may be mounted to samples having a generally non-flat surface (e.g., a curved outer surface) or even sample a relatively flat and uniform surface. This characteristic of the ultrasonic transducer assembly 20 allows the device to maintain an adequate physical contact between the ultrasonic transducer assembly 20 and the sample under investigation. As a result, each transducer 32a, 32b, . . . , 32b may be configured to deliver ultrasound more effectively than existing solutions.

In some embodiments, the support 22 is a sheet made from a metal or a metal alloy. The expression “sheet” is herein used to refer a material or layer being thin enough to allow the material or layer to be curved, bent, compressed and the like.

In some embodiments, the ultrasonic transducer assembly 20 may include a second support 46. The distal end 28 of the flexible printed circuit board 24 may be affixed to the second support 46. As illustrated in FIG. 1, the second support 46 is not in direct contact with the support 22. Alternatively, there may be a physical or mechanical contact between the support 22 and the second support 46. It will be noted that the second support 46 may be rigid or flexible. In some embodiments, the second support 46 may have the same mechanical properties as the support 22.

In some embodiments, the flexible printed circuit board 24 includes a plurality of conducting layers. In this configuration, each conducting layer includes at least one of the conductive channels 36a, 36b, . . . , 36n. The flexible printed circuit board 24 may include at least one insulating layer. In this configuration, each insulating layer is provided between two successive layers of the plurality of the conducting layers. The conducting layer(s) and the insulating layer(s) are horizontally extending with respect to the surface of the flexible printed circuit board 24, i.e., the conducting layer(s) and the insulating layer(s) are parallel to the surface of the flexible printed circuit board 24 and are vertically stacked. It will be readily understood that the flexible printed circuit board 24 may also include only one conducting layer.

In terms of dimensions, the ultrasonic transducer assembly 20 has a thickness of about 4 mm or less, 3 mm or less, 2 mm or less, or 1 mm or less. The other dimensions may vary according to the targeted applications.

In operation, the array of transducers 32 is configured to generate ultrasound (or, alternatively, an “ultrasonic beam”) having a center frequency comprised in the range extending from about 0.5 MHz to about 50 MHz.

The ultrasonic transducer assembly 20 may include, in some embodiments, a cladding or a shield (not shown) covering at least a portion of the flexible printed circuit board 24. The cladding has mechanical properties and electrical properties that allows protecting the flexible printed circuit board 24. For example, and without being limitative, the mechanical properties may comprise mechanical resistance and the electrical properties may comprise electrical insulation.

The ultrasonic transducer assembly 20 may further include a seal (not shown) extending over at least a portion the support 22, at least a portion of the array of transducers 32 and/or at least a portion of the flexible printed circuit board 24. The array of transducers 32 and the flexible printed circuit board 24 (or at least a portion thereof, e.g., the proximal end) are sandwiched between the support 22 and the seal. The seal may be made from an electrically insulating material.

Advantageously, the configuration of the ultrasonic transducer assembly 20, and more particularly the configuration of the flexible printed circuit board 24 may be useful for applications in which a relatively great number of transducers may be required on a relatively small surface area (i.e., a relatively high density). Indeed, as illustrated in FIG. 1, the fact that the power unit 34, which may be operated to drive, power and/or control the array of transducers 32, is offset from the array of transducers allows for a higher density of transducers on the support 22 near the sample. More specifically, the physical separation between the power unit 34 (mounted at the distal end 28 of the flexible printed circuit board 24) and the array of transducers 32 (mounted at the proximal end 26 of the flexible printed circuit board 24) is such that the presence of the power unit 34 does not physically, electronically and/or operatively interfere with the array of transducers 32. As such, the separation between the “active region” of the ultrasonic transducer assembly 20 (i.e., the array of transducers 32) and the power unit 34 allows integration a higher number of transducers while facilitating their connection. In addition, the configuration of the ultrasonic transducer assembly 20 allows miniaturizing the transducers without the associated problems of requiring small and fragile wires for connecting the transducer(s) 32. It will also be noted that the ultrasonic transducer assembly 20 is able to scan the samples for defects on a surface or a volume of a material. The abovementioned assembly also allows connecting the transducer(s) 32 in a relatively limited space, even in the presence of relatively harsh conditions (e.g., temperature, pressure, and the like). It also allows using wires or cables having sufficient mechanical resistance needs, which minimize or at least reduce the risks of breaking small wires or cables (which may be required when the dimensions of the transducers are small enough).

In some embodiments, the array of transducers 32 may include 2, 4, 8, 16, 32, 64, 128 or 256 transducers.

In some embodiments, the power unit is based on a wired configuration. In this configuration, wires are plugged to the power unit. The power unit may be supported on the second support, as previously described. In some embodiments, connectors or plugs may be provided on the power unit. It will be noted that the power unit serves the function of a connexion zone, which may be particularly useful when the transducers have relatively small dimensions, and that conventional wires or cables cannot be used to connect the transducers. Additionally, the offset configuration of the power unit with respect to the array of transducers may facilitate the interconnexion therebetween.

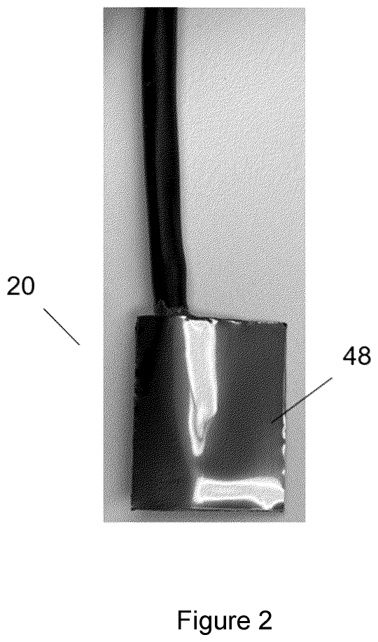

Now turning to FIG. 2, in some embodiments, the ultrasonic transducer assembly 20 may include a flexible cover 48. The flexible cover 48 extends over the seal and may optionally mechanically contact the support 22 through the seal. The flexible cover 48 may be mechanically attached, affixed or fastened to the support 22. Once assembled, the support 22 and the flexible cover 48 may define a casing or an enclosure holding the array of transducers 32 and at least a portion of the flexible printed circuit board 24.

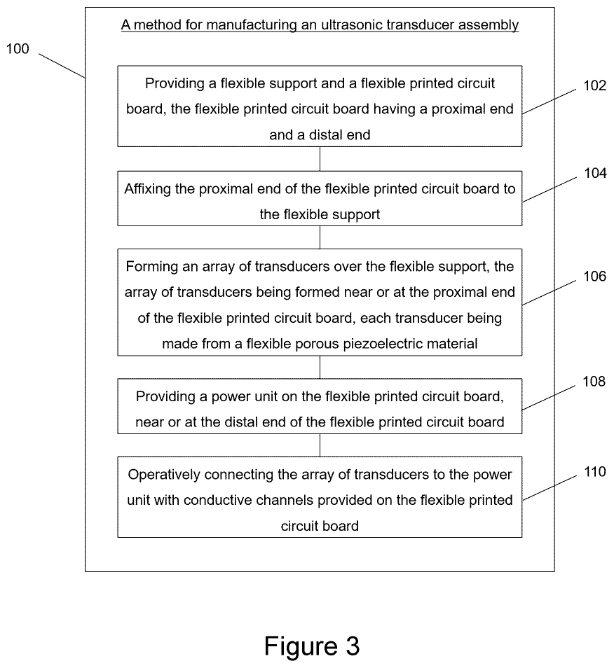

Now turning to FIG. 3, a method 100 for manufacturing the ultrasonic transducer assembly having been herein described will now be presented.

The method 100 includes a step 102 of providing a support and a flexible printed circuit board. The flexible printed circuit board being provided has a proximal end and a distal end, as it has been previously described. The support and the flexible printed circuit board may be manually or automatically provided.

The method 100 also includes a step 104 of affixing the proximal end of the flexible circuit printed board to the support and a step 106 of forming an array of transducers over the support, In the step 106, the array of transducers may be formed near or at the proximal end of the flexible printed circuit board. It will be noted that, in some embodiments, the step 106 may follow the step 104 and that, in other embodiments, the step 106 may precede the step 104.

Once the steps 104 and 106 have been completed, the method 100 includes a step 108 of providing a power unit on the flexible printed circuit board, near or at the distal end of the flexible printed circuit board.

The method 100 then includes a step 110 of operatively connecting the array of transducers to the power unit with conductive channels provided on the flexible printed circuit board.

In some embodiments, the method 100 may include operatively connecting the array of transducers to the flexible printed circuit board. As it has been previously explained, each transducer of the array of transducers comprises a respective transducer contact, and the flexible printed circuit board comprises a plurality of conductive pads positioned near or at the proximal end of the flexible printed circuit board. In these embodiments, the step of operatively connecting the array of transducers to the flexible printed circuit board may include affixing the respective transducer contact with a corresponding conductive pad. For example, and without being limitative, the respective transducer contact may be affixed to the corresponding conductive pad with an electrically conductive glue or an electrically conductive epoxy.

In some embodiments, the method 100 includes providing a second support and affixing the distal end of the flexible printed circuit board to the second support.

In some embodiments, the method 100 includes operatively connecting the power unit to the flexible printed circuit board.

In some embodiments, the method 100 includes forming the conductive channels on the flexible printed circuit board. This step may be achieved using deposition techniques known in the art.

In some embodiments, forming the array of transducers is achieved with a deposition technique.

In some embodiments, the method 100 includes covering at least a portion of the flexible printed circuit board with a cladding. The cladding may have the mechanical properties and electrical properties which have been previously described.

In some embodiments, the method 100 includes providing a seal extending over at least a portion the support, at least a portion of the array of transducers and at least a portion of the flexible printed circuit board. In these embodiments, the array of transducers and the flexible printed circuit board are sandwiched between the support and the seal.

In some embodiments, the method 100 includes providing a flexible cover extending over the seal and mechanically contacting the support.

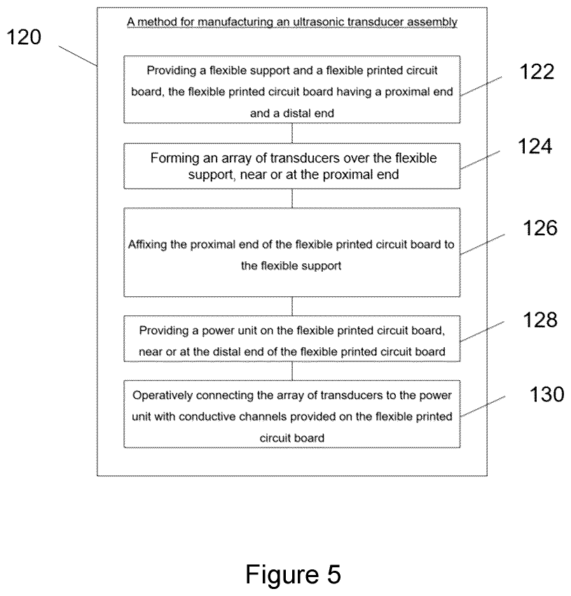

Another embodiment of a method for manufacturing an ultrasonic transducer assembly is illustrated in FIG. 5. The method 120 includes a step 122 of providing a flexible support and a flexible printed circuit board, a step 124 of forming an array of transducers, a step 126 of affixing the flexible printed circuit to the flexible support, a step 128 of providing a power unit on the flexible printed circuit board, and a step 130 of operatively connecting the array of transducers to the power unit. The method 120 may include other steps. In one embodiment, the method 120 includes the deposition of the piezoelectric material on the conductive substrate, the application of a conductive paste on the piezoelectric material, cutting the piezoelectric elements, the installation of the flexible printed circuit, the connection of the flexible printed circuit with the piezoelectric elements, the connection of the ground of the flexible printed circuit with the conductive substrate, the connection of electric wires to the flexible printed circuit, the installation of insulation above the piezoelectric elements, the installation of a sealant on the entire device, and the installation of a flexible cover

Now that different embodiments of a method for manufacturing or producing the ultrasonic transducer assembly have been presented, a method for inspecting a sample will now be described.

The method for inspecting the sample includes a step of contacting the sample with the ultrasonic transducer assembly which has been previously described. Once the ultrasonic transducer is in contact with the sample, the method includes a step of obtaining a sample signal representative of at least one property of the sample. In some embodiments, the method may include driving the ultrasonic transducer assembly to generate an interrogating acoustic signal towards the sample. The interrogating acoustic signal interacts with the sample to produce the sample signal. In some embodiments, the method may include a step of collecting the sample signal. It will be readily understood that the expression “collecting” may encompass various embodiments, such as, for example, and without being limitative, detecting the sample signal with a detector. In some embodiments, the method may include processing the sample signal to determine the at least one property of the sample.

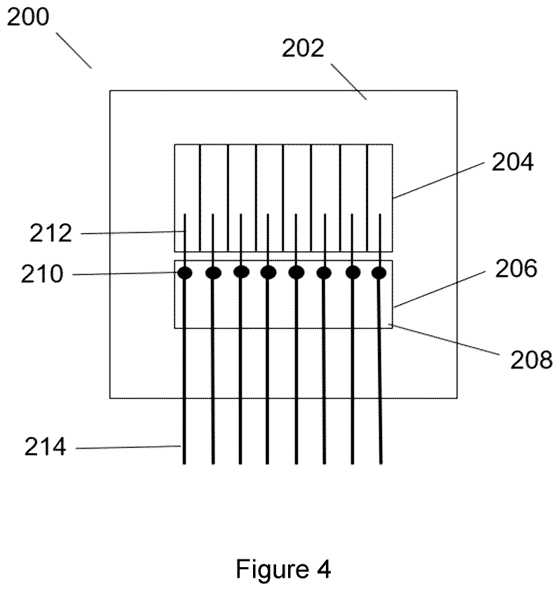

Now turning to FIG. 4, another embodiment of the technology will now be presented.

An ultrasonic transducer assembly 200 for inspecting a sample is illustrated in FIG. 4. The ultrasonic transducer assembly 200 includes a conductive substrate 202. The ultrasonic transducer assembly 200 also includes an array of transducers 204 disposed on the conductive substrate 202. Each transducer is made from a flexible porous piezoelectric material. In some embodiments, the transducers 204 are similar to the ones having been previously described. The ultrasonic transducer assembly 200 also includes a flexible printed circuit board 206. The flexible printed circuit board 206 includes a flexible substrate 208 having an outer perimeter. The flexible substrate 208 contacts the conductive substrate 202. The flexible printed circuit board 206 also includes a plurality of electrical contacts 210 distributed across a surface of the flexible printed circuit board 206. The contacts 210 are provided is a region that is confined within the outer perimeter (i.e., they are not provided along the perimeter of the flexible printed circuit board 206). The flexible printed circuit board 206 also includes a plurality of channels 212 contacting a portion of the outer perimeter of the flexible substrate 208 and extending outwardly therefrom (i.e., an extremity of each channel 212 contacts the perimeter of the flexible substrate 208, and another one of the extremity of each channel 212 extends away from the flexible substrate 208 and towards the array of transducers 204). Each channel 212 is operatively connected to a respective transducer of the array of transducers 204 and a respective electrical contact of said plurality of electrical contacts 210. The ultrasonic transducer assembly 200 also includes an electrical circuit 214 configured to power the array of transducers 204. The electrical circuit 214 comprising a plurality of electrical connections, such as, for examples, wires, operatively connected to a respective electrical contact of said plurality of electrical contacts 210.

There is also provided a method for manufacturing an ultrasonic transducer assembly as illustrated in FIG. 4. The method includes providing an array of transducers disposed on a conductive substrate, each transducer being made from a flexible porous piezoelectric material; providing a flexible printed circuit board, the flexible printed circuit comprising a flexible substrate having an outer perimeter, a plurality of electrical contacts distributed across a surface of the flexible printed circuit board and within the outer perimeter, and a plurality of channels; connecting each channel with a respective transducer of the array of transducers; providing an electrical circuit configured to power the array of transducers, the electrical circuit comprising a plurality of electrical connections; and connecting each electrical connection to a respective electrical contact of said plurality of electrical contacts of said plurality of channels.

There is also provided a method for inspecting a sample using the ultrasonic transducer illustrated in FIG. 4. The method includes contacting the sample with the ultrasonic transducer assembly and obtaining a sample signal representative of at least one property of the sample.

Several alternative embodiments and examples have been described and illustrated herein. The embodiments described above are intended to be exemplary only. A person skilled in the art would appreciate the features of the individual embodiments, and the possible combinations and variations of the components. A person skilled in the art would further appreciate that any of the embodiments could be provided in any combination with the other embodiments disclosed herein. The present examples and embodiments, therefore, are to be considered in all respects as illustrative and not restrictive. Accordingly, while specific embodiments have been illustrated and described, numerous modifications come to mind without significantly departing from the scope defined in the current description and the appended claims.

1-87. (canceled)

88. An ultrasonic transducer assembly for inspecting a sample, the ultrasonic transducer assembly comprising:
a support;
a flexible printed circuit board having a proximal end and a distal end, the proximal end being affixed to the support and the distal end extending away from the support;
an array of transducers mounted on the support and positioned near or at the proximal end of the flexible printed circuit board, each transducer being made from a flexible porous piezoelectric material and being operatively connected to the flexible printed circuit board; and
a power unit mounted on the flexible printed circuit board and positioned near or at the distal end of the flexible printed circuit board, the power unit being operatively connected to the flexible printed circuit board;
wherein the flexible printed circuit board comprises conductive channels operatively connecting the array of transducers to the power unit.

89. The ultrasonic transducer assembly of claim 88, wherein the support is a sheet made from a metal or a metal alloy.

90. The ultrasonic transducer assembly of claim 88, wherein the support is flexible.

91. The ultrasonic transducer assembly of claim 88, wherein the support is rigid.

92. The ultrasonic transducer assembly of claim 88, wherein each transducer of the array of transducers comprises a respective transducer contact and the flexible printed circuit board comprises a plurality of conductive pads positioned near or at the proximal end of the flexible printed circuit board, the respective transducer contact being in electrical communication with a corresponding conductive pad.

93. The ultrasonic transducer assembly of claim 88, wherein the power unit comprises wires, connectors, or plugs.

94. The ultrasonic transducer assembly of claim 88, wherein the flexible printed circuit board comprises at least one ground.

95. The ultrasonic transducer assembly of claim 88, further comprising a second support, the distal end of the flexible printed circuit board being affixed to the second support.

96. The ultrasonic transducer assembly of claim 95, wherein the second support is rigid.

97. The ultrasonic transducer assembly of claim 95, wherein the second support is flexible.

98. The ultrasonic transducer assembly of claim 88, wherein the flexible printed circuit board comprises a plurality of conducting layers, each conducting layer comprising at least one of the conductive channels, the flexible printed circuit board comprising at least one insulating layer, each insulating layer being provided between two successive layers of the plurality of the conducting layers.

99. The ultrasonic transducer assembly of claim 88, wherein the number of conductive channels is comprised between 2 and 256, 2 to 128, 2 to 64, 2 to 32, 2 to 16, 2 to 8, or 2 to 4.

100. The ultrasonic transducer assembly of claim 88, wherein the array of transducers is configured to generate ultrasound having a center frequency comprised in a frequency range extending from about 0.5 MHz to about 50 MHz.

101. The ultrasonic transducer assembly of claim 88, wherein the array of transducers has a constant pitch.

102. The ultrasonic transducer assembly of claim 88, wherein the array of transducers has a variable pitch.

103. The ultrasonic transducer assembly of claim 88, further comprising a cladding covering at least a portion of the flexible printed circuit board, the cladding having mechanical properties and electrical properties, the mechanical properties comprising mechanical resistance and the electrical properties comprising electrical insulation.

104. The ultrasonic transducer assembly of claim 88, further comprising a seal extending over at least a portion the support, at least a portion of the array of transducers and at least a portion of the flexible printed circuit board, wherein the array of transducers and the flexible printed circuit board are sandwiched between the support and the seal, the seal being made from an electrically insulating material, and the ultrasonic transducer assembly further comprising a flexible cover, the flexible cover extending over the seal and mechanically contacting the support through the seal.

105. A method for manufacturing an ultrasonic transducer assembly, the method comprising:
providing a support and a flexible printed circuit board, the flexible printed circuit board having a proximal end and a distal end;
affixing the proximal end of the flexible printed circuit board to the support;
forming an array of transducers over the support, the array of transducers being formed near or at the proximal end of the flexible printed circuit board, each transducer being made from a flexible porous piezoelectric material;
providing a power unit on the flexible printed circuit board, near or at the distal end of the flexible printed circuit board; and
operatively connecting the array of transducers to the power unit with conductive channels provided on the flexible printed circuit board.

106. An ultrasonic transducer assembly for inspecting a sample, the ultrasonic transducer assembly comprising:
a support;
a flexible printed circuit board having a proximal end and a distal end, the proximal end being affixed to the support and the distal end extending away from the support;
a transducer mounted on the support and positioned near or at the proximal end of the flexible printed circuit board, the transducer being made from a flexible porous piezoelectric material and being operatively connected to the flexible printed circuit board; and
a power unit mounted on the flexible printed circuit board and positioned near or at the distal end of the flexible printed circuit board, the power unit being operatively connected to the flexible printed circuit board;
wherein the flexible printed circuit board comprises conductive channels operatively connecting the transducer to the power unit.

107. An ultrasonic transducer assembly for inspecting a sample, the ultrasonic transducer assembly comprising:
a conductive substrate;
an array of transducers disposed on the conductive substrate, each transducer being made from a flexible porous piezoelectric material;
a flexible printed circuit board, comprising:
a flexible substrate having an outer perimeter, the flexible substrate contacting the conductive substrate;
a plurality of electrical contacts distributed across a surface of the flexible printed circuit board and within the outer perimeter; and
a plurality of channels contacting a portion of the outer perimeter and extending outwardly therefrom, each channel being operatively connected to a respective transducer of the array of transducers and a respective electrical contact of said plurality of electrical contacts; and
an electrical circuit configured to power the array of transducers, the electrical circuit comprising a plurality of electrical connections operatively connected to a respective electrical contact of said plurality of electrical contacts.
